(19) United States
(12) Patent Application Publication
(10) Pub. No.: US 2025/0331102 A1
(43) Pub. Date: Oct. 23, 2025

(54) FLEXIBLE ELECTRONIC DEVICE

(71) Applicant: Innolux Corporation, Miaoli County (TW)

(72) Inventor: Tsung-Yu Huang, Miaoli County (TW)

(73) Assignee: Innolux Corporation, Miaoli County (TW)

(21) Appl. No.: 19/079,487

(22) Filed: Mar. 14, 2025

(30) Foreign Application Priority Data
Apr. 17, 2024 (CN) 202410462627.2

(51) Int. Cl. H05K 1/02

(52) U.S. Cl. CPC H05K 1/0277

(57) ABSTRACT

A flexible electronic device includes a first flexible substrate, a circuit layer disposed on a first adhesive layer, a first support layer, a second support layer and a second adhesive layer. The circuit layer includes a driving circuit and electronic components electrically connected to the driving circuit. The first adhesive layer is disposed between the first flexible substrate and the first support layer. The second adhesive layer is disposed between the second support layer and the circuit layer. A Young's modulus of the first support layer is greater than that of the first adhesive layer, and a Young's modulus of the second support layer is greater than that of the second adhesive layer. A thickness of the first support layer is less than that of the first adhesive layer, and a thickness of the second support layer is less than that of the second support layer.

### CROSS-REFERENCE TO RELATED APPLICATION

This application claims the priority benefit of China application serial no. 202410462627.2, filed on Apr. 17, 2024. The entirety of the above-mentioned patent application is hereby incorporated by reference herein and made a part of this specification.

### BACKGROUND

### Technical Field

The disclosure relates to a flexible electronic device, and in particular relates to a flexible electronic device that may enhance bend strength or increase repeated bending capability (number of times).

### Description of Related Art

Electronic devices or spliced electronic devices have been widely used in various fields such as communication, display, automotive, or aviation, etc. With the vigorous development of electronic devices, the electronic devices are being developed towards thinness and lightness, which has led to higher requirements for the reliability or quality of the electronic devices.

### SUMMARY

A flexible electronic device that may enhance bend strength or increase repeated bending capability (number of times) is provided in the disclosure.

According to an embodiment of the disclosure, a flexible electronic device includes a first flexible substrate, a circuit layer, a first support layer, a first adhesive layer, a second support layer, and a second adhesive layer. The circuit layer is disposed on the first flexible substrate.

The circuit layer includes a driving circuit and an electronic component electrically connected to the driving circuit. The first support layer is disposed under the first flexible substrate. The first adhesive layer is disposed between the first flexible substrate and the first support layer. The second support layer is disposed on the circuit layer. The second adhesive layer is disposed between the second support layer and the circuit layer. A Young's modulus of the first support layer is greater than a Young's modulus of the first adhesive layer, and a Young's modulus of the second support layer is greater than a Young's modulus of the second adhesive layer. A thickness of the first support layer is less than a thickness of the first adhesive layer, and a thickness of the second support layer is less than a thickness of the second support layer.

### BRIEF DESCRIPTION OF THE DRAWINGS

The accompanying drawings are included to provide a further understanding of the disclosure, and are incorporated in and constitute a part of this specification. The drawings illustrate embodiments of the disclosure, and together with the description serve to explain principles of the disclosure.

FIG. 1A is a cross-sectional schematic diagram of a flexible electronic device of a first embodiment of the disclosure.

FIG. 1B shows the stress test result when the flexible electronic device of FIG. 1A is bent.

FIG. 2A is a cross-sectional schematic diagram of a flexible electronic device of a second embodiment of the disclosure.

FIG. 2B shows the stress test result when the flexible electronic device of FIG. 2A is bent.

FIG. 3A is a cross-sectional schematic diagram of a flexible electronic device of a third embodiment of the disclosure.

FIG. 3B shows the stress test result when the flexible electronic device of FIG. 3A is bent.

FIG. 4 is a cross-sectional schematic diagram of a flexible electronic device of a fourth embodiment of the disclosure.

FIG. 5A is a cross-sectional schematic diagram of a flexible electronic device of a fifth embodiment of the disclosure.

FIG. 5B shows the stress test result when the flexible electronic device of FIG. 5A is bent.

FIG. 6 is a cross-sectional schematic diagram of a flexible electronic device of a sixth embodiment of the disclosure.

FIG. 7A is a cross-sectional schematic diagram of a flexible electronic device of a seventh embodiment of the disclosure.

FIG. 7B shows the stress test result when the flexible electronic device of FIG. 7A is bent.

FIG. 8A is a cross-sectional schematic diagram of a flexible electronic device of an eighth embodiment of the disclosure.

FIG. 8B shows the stress test result when the flexible electronic device of FIG. 8A is bent.

### DETAILED DESCRIPTION OF DISCLOSED EMBODIMENTS

The disclosure may be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

In the following description and claims, words such as “comprising” and “including” are open-ended words, so they should be interpreted as meaning “including but not limited to . . . ”.

It should be understood that when an element or layer is referred to as being “on” or “connected to” another element or layer, it may be directly on or directly connected to this other element or layer, or there may be an intervening element or layer in between (indirect case). In contrast, when an element is referred to as being “directly on” or “directly connected to” another element or layer, there are no intervening elements or layers present.

Although the terms “first”, “second”, “third”, . . . may be used to describe various constituent elements, the constituent elements are not limited by the terms. The terms are only used to distinguish a single constituent element from other constituent elements in the specification. The same terms may not be used in the claim, but replaced by first, second, third . . . according to the order in which the elements are declared in the claim. Therefore, in the following description, the first constituent element may be the second constituent element in the claim.

As used herein, the terms “about,” “approximately,” “substantially,” and “roughly” generally mean within 10%, within 5%, within 3%, within 2%, within 1%, or within 0.5% of a given value or range. The quantity given here is an approximate quantity, that is, even though “about,” “approximately,” “substantially,” and “roughly” are not specified, the meaning of “about,” “approximately,” “substantially,” and “roughly” are still implied.

In some embodiments of the disclosure, terms related to joining and connecting, such as “connected”, “interconnected”, etc., unless otherwise defined, may mean that two structures are in direct contact, or may also mean that two structures are not in direct contact, in which there are other structures located between these two structures. The terms related to joining and connecting may also include the case where both structures are movable, or both structures are fixed. Furthermore, the term “coupled” includes any direct and indirect means of electrical connection.

In some embodiments of the disclosure, optical microscopy (OM), scanning electron microscope (SEM), film thickness profiler (a-step), ellipsometer, or other suitable methods may be used to measure the area, width, thickness, or height of each element, or the distance or pitch between elements. In detail, according to some embodiments, a scanning electron microscope may be used to obtain a cross-sectional structure image including a component to be measured, and to measure the area, width, thickness, or height of each element, or the distance or pitch between elements.

In the disclosure, the electronic device may include a display device, a light-emitting device, a backlight device, a virtual reality device, an augmented reality (AR) device, an antenna device, a sensing device, a splicing device or any combination thereof, but not limited thereto. The display device may be a non-self-luminous display or a self-luminous display according to requirements, and may be a color display or a monochrome display according to requirements.

The antenna device may be a liquid crystal antenna device or a non-liquid crystal antenna device, the sensing device may be a sensing device for sensing capacitance, light, heat or ultrasonic waves, and the splicing device may be a display splicing device or an antenna splicing device, but not limited thereto. Electronic components in electronic devices may include passive and active components, such as capacitors, resistors, inductors, diodes, transistors, etc. The diode may include a light-emitting diode (LED) or a photodiode. The light emitting diode may include, for example, an organic light emitting diode (OLED), a mini light emitting diode (mini LED), a micro light emitting diode (micro LED), or a quantum dot light emitting diode (quantum dot LED), but not limited thereto. The transistor may include, for example, a top gate thin film transistor, a bottom gate thin film transistor, or a dual gate thin film transistor, but not limited thereto. The electronic device may also include fluorescence materials, phosphor materials, quantum dot (QD) materials, or other suitable materials according to requirements, but not limited thereto. The electronic device may have a peripheral system such as a driving system, a control system, a light source system, and the like to support a display device, an antenna device, a wearable device (e.g., including augmented reality or virtual reality devices), an in-vehicle device (e.g., including car windshields), or a splicing device. It should be noted that, the electronic device may be any arrangement and combination of the foregoing, but not limited thereto. Hereinafter, a flexible electronic device is used to illustrate the disclosure, but the disclosure is not limited thereto.

It should be noted that, in the following embodiments, the features in several different embodiments may be replaced, reorganized, and mixed to complete other embodiments without departing from the spirit of the disclosure. As long as the features of the various embodiments do not violate the spirit of the disclosure or conflict with one another, they may be mixed and matched arbitrarily.

References of the exemplary embodiments of the disclosure are to be made in detail. Examples of the exemplary embodiments are illustrated in the drawings. If applicable, the same reference numerals in the drawings and the descriptions indicate the same or similar parts.

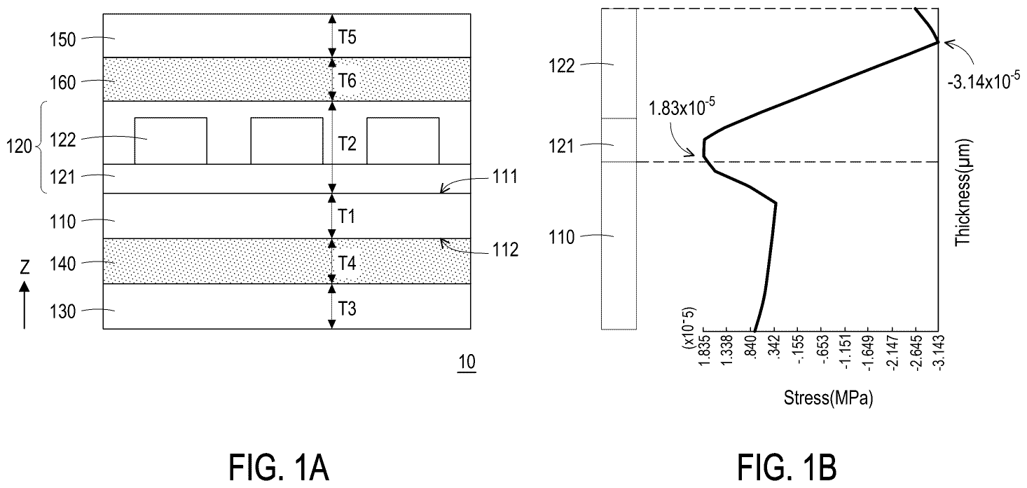

FIG. 1A is a cross-sectional schematic diagram of a flexible electronic device of a first embodiment of the disclosure. FIG. 1B shows the stress test result when the flexible electronic device of FIG. 1A is bent. Referring to FIG. 1A, a flexible electronic device 10 of the disclosure includes a first flexible substrate 110, a circuit layer 120, a first support layer 130, a first adhesive layer 140, a second support layer 150, and a second adhesive layer 160.

Specifically, the first flexible substrate 110 has a first surface 111 and a second surface 112 opposite to each other. The first flexible substrate 110 has a thickness T1, and the thickness T1 may be the thickness of the first flexible substrate 110 measured along the direction Z (i.e., the normal direction of the first flexible substrate 110). In this embodiment, the thickness T1 of the first flexible substrate 110 may be, for example, 1 micron (μm) to 100 microns, or 10 microns to 80 microns, but not limited thereto. In this embodiment, the Young's modulus of the first flexible substrate 110 may be, for example, 0.1 GPa to 99 GPa, or 1 GPa to 10 GPa, but not limited thereto. In this embodiment, the first flexible substrate 110 may be a soft substrate. For example, the material of the first flexible substrate 110 may include polycarbonate (PC), polyimide (PI), polyethylene terephthalate (PET), fiber-reinforced plastic (FRP), other suitable plastic materials, or combinations of the foregoing, but not limited thereto.

The circuit layer 120 is disposed on the first surface 111 of the first flexible substrate 110. The circuit layer 120 includes a driving circuit 121 and electronic components 122. The electronic component 122 is disposed on the driving circuit 121. The electronic component 122 may be electrically connected to the driving circuit 121, and the driving circuit 121 may drive the electronic component 122. In this embodiment, the circuit layer 120 has a thickness T2, and the thickness T2 may be the thickness of the circuit layer 120 measured along the direction Z. In this embodiment, the thickness T2 of the circuit layer 120 may be, for example, 1 micron to 50 microns, but not limited thereto. In this embodiment, the driving circuit 121 may include driving circuits (not shown) such as transistors, scan lines, and data lines, and the electronic components 122 may include organic light-emitting diodes, mini light-emitting diodes, micro light-emitting diodes, quantum dot light-emitting diodes, or a combination of the above, but not limited thereto.

The first support layer 130 is disposed under the second surface 112 of the first flexible substrate 110. The first support layer 130 has a thickness T3, and the thickness T3 may be the thickness of the first support layer 130 measured along the direction Z. In this embodiment, the thickness T3 of the first support layer 130 may be, for example, 25 microns to 500 microns, or 50 microns to 400 microns, but not limited thereto. In this embodiment, the Young's modulus of the first support layer 130 may be, for example, 0.1 GPa to 99 GPa, or 1 GPa to 10 GPa, but not limited thereto. In this embodiment, the first support layer 130 may be a rigid substrate, a soft substrate, or a combination of the foregoing. For example, the material of the first support layer 130 may include metal, glass, polycarbonate, polyimide, polyethylene terephthalate, other suitable support materials, or combinations thereof, but not limited thereto.

The first adhesive layer 140 is disposed between the first flexible substrate 110 and the first support layer 130. The first adhesive layer 140 may be configured to bond the first flexible substrate 110 and the first support layer 130. The first adhesive layer 140 has a thickness T4, and the thickness T4 may be the thickness of the first adhesive layer 140 measured along the direction Z. In this embodiment, the thickness T4 of the first adhesive layer 140 may be, for example, 25 microns to 600 microns, or 50 microns to 500 microns, but not limited thereto. In this embodiment, the thickness T4 of the first adhesive layer 140 may be greater than the thickness T3 of the first support layer 130, and the ratio of the thickness T3 of the first support layer 130 to the thickness T4 of the first adhesive layer 140 may be greater than 1/24 and less than 1 (i.e., 1/24<T3/T4<1), but not limited thereto. In this embodiment, the Young's modulus of the first adhesive layer 140 may be, for example, 0.1 KPa to 10 GPa, or 100 KPa to 5 GPa, but not limited thereto. In this embodiment, the material of the first adhesive layer 140 may include thermosetting glue, UV glue, or a combination of the foregoing. For example, the material of the first adhesive layer 140 may include optically clear adhesive (OCA), optically clear resin (OCR), pressure sensitive adhesives (PSA), other suitable adhesive materials, or a combination thereof, but not limited thereto.

The second support layer 150 is disposed on the circuit layer 120. The second support layer 150 has a thickness T5, and the thickness T5 may be the thickness of the second support layer 150 measured along the direction Z. In this embodiment, the thickness T5 of the second support layer 150 may be, for example, 10 microns to 210 microns, or 20 microns to 180 microns, but not limited thereto. In this embodiment, the Young's modulus of the second support layer 150 may be, for example, 0.1 GPa to 99 GPa, or 1 GPa to 10 GPa, but not limited thereto. In this embodiment, the second support layer 150 may be a polarizer or an anti-reflective conductive film, but not limited thereto.

The second adhesive layer 160 is disposed between the second support layer 150 and the circuit layer 120. The second adhesive layer 160 may be configured to bond the second support layer 150 and the circuit layer 120. The second adhesive layer 160 has a thickness T6, and the thickness T6 may be the thickness of the second adhesive layer 160 measured along the direction Z. In this embodiment, the thickness T6 of the second adhesive layer 160 may be, for example, microns to 300 microns, or 20 microns to 250 microns, but not limited thereto. In this embodiment, the thickness T6 of the second adhesive layer 160 may be greater than the thickness T5 of the second support layer 150, and the ratio of the thickness T5 of the second support layer 150 to the thickness T6 of the second adhesive layer 160 may be greater than 1/30 and less than 1 (i.e., 1/30<T5/T6<1), but not limited thereto. In this embodiment, the Young's modulus of the second adhesive layer 160 may be, for example, 0.1 KPa to 10 GPa, or 100 KPa to 5 GPa, but not limited thereto. In this embodiment, the material of the second adhesive layer 160 may include thermosetting glue, UV glue, or a combination of the foregoing. For example, the material of the second adhesive layer 160 may include optically clear adhesive (OCA), optically clear resin (OCR), pressure sensitive adhesives (PSA), other suitable adhesive materials, or a combination thereof, but not limited thereto.

In this embodiment, by setting the Young's modulus of the first support layer 130 greater than the Young's modulus of the first adhesive layer 140, the Young's modulus of the second support layer 150 greater than the Young's modulus of the second adhesive layer 160, the thickness T3 of the first support layer 130 less than the thickness T4 of the first adhesive layer 140, and the thickness T5 of the second support layer 150 less than the thickness T6 of the second adhesive layer 160, the circuit layer 120 may be substantially located at the neutral axis when the flexible electronic device 10 is bent. The “neutral axis” refers to the area that is least affected by stress when the flexible electronic device 10 is bent. Specifically, “neutral axis” refers to the interface between the tensile zone and the compression zone of a structure when it is bent. The structure located at this interface (neutral axis) is neither subjected to compression nor tension. In other words, the positive and negative stresses at each point on the neutral axis may approach zero. In this embodiment, since the circuit layer 120 may be substantially located on the neutral

axis of the flexible electronic device 10, the stress applied to the circuit layer 120 when the flexible electronic device 10 is bent may be reduced. This design may enhance the bend strength of the flexible electronic device 10 or improve the repeated bending capability (number of times) of the flexible electronic device 10, thereby reducing damage to the circuit layer 120 (e.g., circuit breakage or component damage) causing the flexible electronic device 10 to fail to operate normally (e.g., light up).

Referring to FIG. 1B, in the stress test result when the flexible electronic device 10 of this embodiment is bent, the stress of the driving circuit 121 is approximately 1.83×10⁻⁵ MPa, and the stress of the electronic component 122 is approximately −3.14×10⁻⁵ MPa. Since the positive stress of the driving circuit 121 and the negative stress of the electronic component 122 may both approach zero when the flexible electronic device 10 is bent, this indicates that the circuit layer 120 may be substantially located on the neutral axis when the flexible electronic device 10 is bent. In this disclosure, positive stress refers to tensile stress, and negative stress refers to compressive stress. The stress value disclosed in each embodiment represents the maximum stress value that the layer bears when bending.

In some embodiments, the stress of the circuit layer 120 may be further reduced or brought closer to zero by changing the stack thickness and/or adding other stack layers in the flexible electronic device 10.

For example, if the thickness of the first support layer 130 in the flexible electronic device 10 is doubled (i.e., when the thickness of the first support layer 130 is 50 microns to 1000 microns or 100 microns to 800 microns), the stress of the driving circuit 121 may be reduced to approximately 4.22×10⁻⁷ MPa, and the stress of the electronic component 122 may be reduced to approximately −1.38×10⁻⁷ MPa.

If the thickness of the first flexible substrate 110 in the flexible electronic device 10 is doubled (i.e., when the thickness of the first flexible substrate 110 is 2 microns to 200 microns), the stress of the driving circuit 121 may be reduced to approximately 1.2×10⁻⁶ MPa, and the stress of the electronic component 122 may be reduced to approximately −6.08×10⁻⁶ MPa.

If the thickness of the first flexible substrate 110 and the thickness of the first support layer 130 in the flexible electronic device 10 are both doubled (i.e., when the thickness of the first flexible substrate 110 is 2 microns to 200 microns, and the thickness of the first support layer 130 is 50 microns to 1000 microns or 100 microns to 800 microns), the stress of the driving circuit 121 may be reduced to approximately 1.61×10⁻⁷ MPa, the stress of the electronic component 122 may be reduced to approximately −9.08×10⁻⁸ MPa, and the stress of the first flexible substrate 110 may be reduced to approximately 1.36×10⁻⁷ MPa.

Other embodiments are described below for illustrative purposes. It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

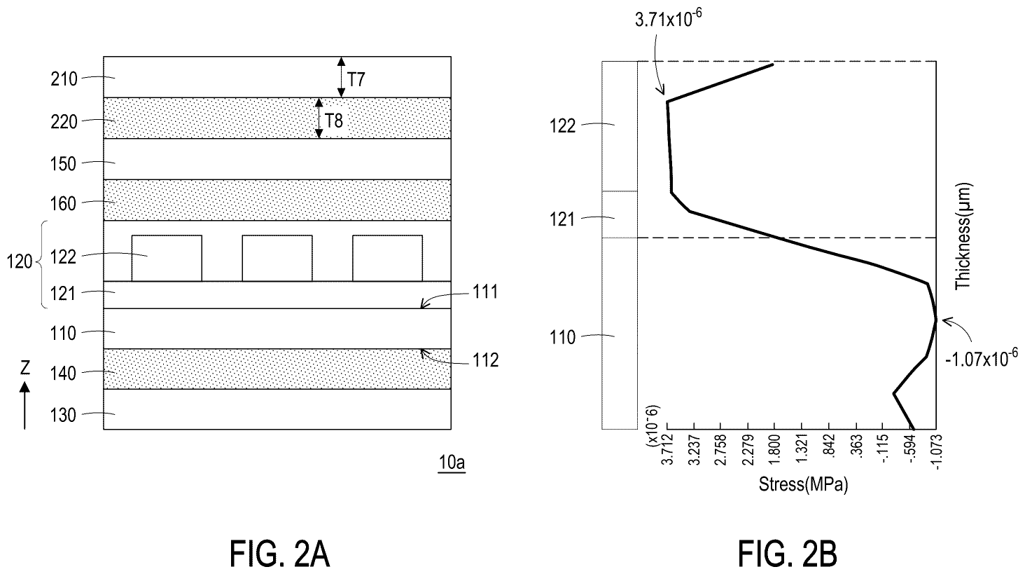

FIG. 2A is a cross-sectional schematic diagram of a flexible electronic device of a second embodiment of the disclosure. FIG. 2B shows the stress test result when the flexible electronic device of FIG. 2A is bent. Referring to FIG. 2A and FIG. 1A at the same time, the flexible electronic device 10a of this embodiment is similar to the flexible electronic device 10 of FIG. 1A. The only difference between the two is that the flexible electronic device 10a of this embodiment also includes an anti-scattering film (ASF) 210 and a third adhesive layer 220.

Specifically, referring to FIG. 2A, the anti-scattering film 210 is disposed on the second support layer 150 so that the second support layer 150 is located between the anti-scattering film 210 and the circuit layer 120. The anti-scattering film 210 has a thickness T7, and the thickness T7 may be the thickness of the anti-scattering film 210 measured along the direction Z. In this embodiment, the thickness T7 of the anti-scattering film 210 may be, for example, 10 microns to 100 microns, but not limited thereto. In this embodiment, the Young's modulus of the anti-scattering film 210 may be, for example, 0.1 GPa to 99 GPa, or 1 GPa to 10 GPa, but not limited thereto.

The third adhesive layer 220 is disposed between the anti-scattering film 210 and the

film 210 and the second support layer 150. The third adhesive layer 220 has a thickness T8, and the thickness T8 may be the thickness of the third adhesive layer 220 measured along the direction Z. In this embodiment, the thickness T8 of the third adhesive layer 220 may be, for example, 10 microns to 300 microns, or 20 microns to 250 microns, but not limited thereto.

In this embodiment, the thickness T8 of the third adhesive layer 220 may be less than the thickness T7 of the anti-scattering film 210, but not limited thereto. In this embodiment, the Young's modulus of the third adhesive layer 220 may be, for example, 0.1 KPa to 10 GPa, or 100 KPa to 5 GPa, but not limited thereto. In this embodiment, the material of the third adhesive layer 220 may include thermosetting glue, UV glue, or a combination of the foregoing. For example, the material of the third adhesive layer 220 may include optically clear adhesive (OCA), optically clear resin (OCR), pressure sensitive adhesives (PSA), other suitable adhesive materials, or a combination thereof, but not limited thereto.

Referring to FIG. 2B, in the stress test result when the flexible electronic device 10a of this embodiment is bent, the stress of the electronic component 122 is reduced to approximately 3.71×10⁻⁶ MPa, and the stress of the first flexible substrate 110 is reduced to approximately −1.07×10⁻⁶ MPa.

Therefore, in this embodiment, by adding the anti-scattering film 210 and the third adhesive layer 220, setting the Young's modulus of the anti-scattering film 210 greater than the Young's modulus of the third adhesive layer 220, and the thickness T7 of the anti-scattering film 210 greater than the thickness T8 of the third adhesive layer 220, the stress of the circuit layer 120 and the first flexible substrate 110 may be further reduced or brought closer to zero. This design may enhance the bend strength of the flexible electronic device 10a or improve the repeated bending capability (number of times) of the flexible electronic device 10a, thereby reducing damage to the circuit layer 120 (e.g., circuit breakage or component damage) causing the flexible electronic device 10a to fail to operate normally (e.g., light up).

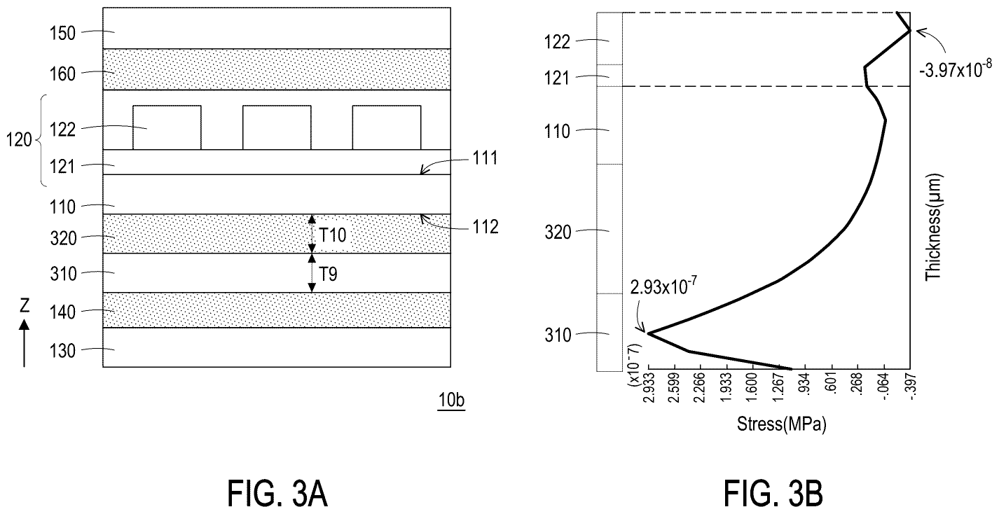

FIG. 3A is a cross-sectional schematic diagram of a flexible electronic device of a third embodiment of the disclosure. FIG. 3B shows the stress test result when the flexible electronic device of FIG. 3A is bent. Referring to FIG. 3A and FIG. 1A at the same time, the flexible electronic device 10b of this embodiment is similar to the flexible electronic device 10 of FIG. 1A. The only difference between the two is that the flexible electronic device 10b of this embodiment also includes a second flexible substrate 310 and a fourth adhesive layer 320.

Specifically, refer to FIG. 3A, the second flexible substrate 310 is disposed under the second surface 112 of the first flexible substrate 110, and the second flexible substrate 310 is disposed between the first flexible substrate 110 and the first adhesive layer 140. The second flexible substrate 310 has a thickness T9, and the thickness T9 may be the thickness of the second flexible substrate 310 measured along the direction Z. In this embodiment, the thickness T9 of the second flexible substrate 310 may be, for example, 1 micron to 100 microns, or 10 microns to 80 microns, but not limited thereto. In this embodiment, the Young's modulus of the second flexible substrate 310 may be, for example, 0.1 GPa to 99 GPa, or 1 GPa to 10 GPa, but not limited thereto. In this embodiment, the second flexible substrate 310 may be a soft substrate. For example, the material of the second flexible substrate 310 may include polycarbonate, polyimide, polyethylene terephthalate, fiber-reinforced plastic, other suitable plastic materials, or combinations of the foregoing, but not limited thereto.

The fourth adhesive layer 320 is disposed between the first flexible substrate 110 and the second flexible substrate 310. The fourth adhesive layer 320 may be configured to bond the first flexible substrate 110 and the second flexible substrate 310. The fourth adhesive layer 320 has a thickness T10, and the thickness T10 may be the thickness of the fourth adhesive layer 320 measured along the direction Z. In this embodiment, the thickness T10 of the fourth adhesive layer 320 may be, for example, 10 microns to 300 microns, or 20 microns to 250 microns, but not limited thereto. In this embodiment, the Young's modulus of the fourth adhesive layer 320 may be, for example, 0.1 KPa to 10 GPa, or 100 KPa to 5 GPa, but not limited thereto. In this embodiment, the material of the fourth adhesive layer 320 may include thermosetting glue, UV glue, or a combination of the foregoing. For example, the material of the fourth adhesive layer 320 may include optically clear adhesive (OCA), optically clear resin (OCR), pressure sensitive adhesives (PSA), other suitable adhesive materials, or a combination thereof, but not limited thereto.

Referring to FIG. 3B, in the stress test result when the flexible electronic device 10b of this embodiment is bent, the stress of the electronic component 122 is reduced to approximately −3.97×10⁻⁸ MPa, and the stress of the second flexible substrate 310 is approximately 2.93×10⁻⁷ MPa.

Therefore, in this embodiment, by adding the second flexible substrate 310 and the fourth adhesive layer 320, the stress of the circuit layer 120 and the second flexible substrate 310 may be further reduced or brought closer to zero. This design may enhance the bend strength of the flexible electronic device 10b or improve the repeated bending capability (number of times) of the flexible electronic device 10b, thereby reducing damage to the circuit layer 120 (e.g., circuit breakage or component damage) causing the flexible electronic device 10b to fail to operate normally (e.g., light up).

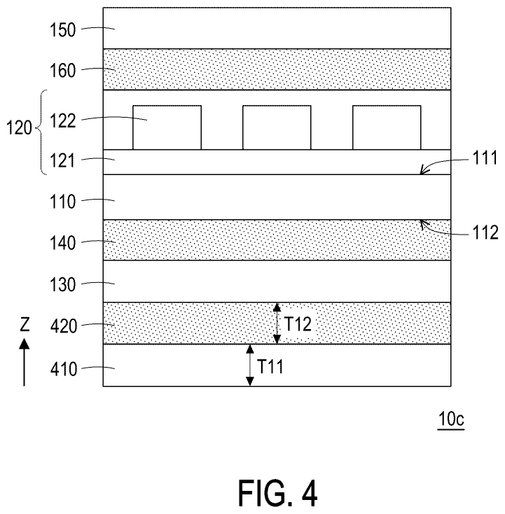

FIG. 4 is a cross-sectional schematic diagram of a flexible electronic device of a fourth embodiment of the disclosure. Referring to FIG. 4 and FIG. 1A at the same time, the flexible electronic device 10c of this embodiment is similar to the flexible electronic device 10 of FIG. 1A. The only difference between the two is that the flexible electronic device 10c of this embodiment also includes a third support layer 410 and a fifth adhesive layer 420.

Specifically, referring to FIG. 4, the third support layer 410 is disposed under the first support layer 130 so that the first support layer 130 is located between the first flexible substrate 110 and the third support layer 410. The third support layer 410 has a thickness T11, and the thickness T11 may be the thickness of the third support layer 410 measured along the direction Z. In this embodiment, the thickness T11 of the third support layer 410 may be, for example, 25 microns to 500 microns, or 50 microns to 400 microns, but not limited thereto. In this embodiment, the Young's modulus of the third support layer 410 may be, for example, 0.1 GPa to 99 GPa, or 1 GPa to 10 GPa, but not limited thereto.

The fifth adhesive layer 420 is disposed between the first support layer 130 and the third support layer 410. The fifth adhesive layer 420 may be configured to bond the first support layer 130 and the third support layer 410. The fifth adhesive layer 420 has a thickness T12, and the thickness T12 may be the thickness of the fifth adhesive layer 420 measured along the direction Z. In this embodiment, the thickness T12 of the fifth adhesive layer 420 may be, for example, 10 microns to 300 microns, or 20 microns to 250 microns, but not limited thereto. In this embodiment, the Young's modulus of the fifth adhesive layer 420 may be, for example, 0.1 KPa to 10 GPa, or 100 KPa to 5 GPa, but not limited thereto. In this embodiment, the material of the fifth adhesive layer 420 may include thermosetting glue, UV glue, or a combination of the foregoing. For example, the material of the fifth adhesive layer 420 may include optically clear adhesive (OCA), optically clear resin (OCR), pressure sensitive adhesives (PSA), other suitable adhesive materials, or a combination thereof, but not limited thereto.

In this embodiment, by adding the third support layer 410 and the fifth adhesive layer 420, the stress of the circuit layer 120 may be further reduced or brought closer to zero. This design may enhance the bend strength of the flexible electronic device 10c or improve the repeated bending capability (number of times) of the flexible electronic device 10c, thereby reducing damage to the circuit layer 120 (e.g., circuit breakage or component damage) causing the flexible electronic device 10c to fail to operate normally (e.g., light up).

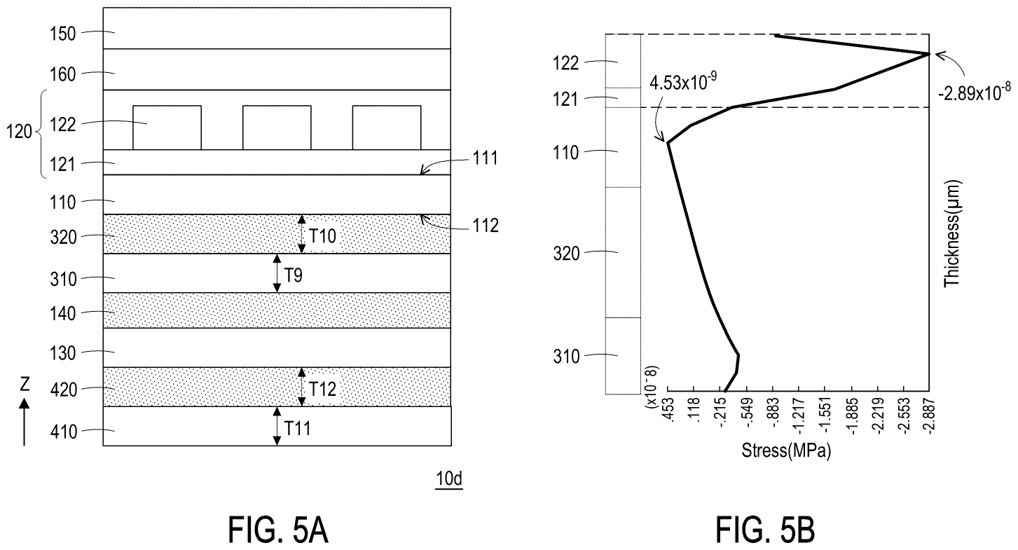

FIG. 5A is a cross-sectional schematic diagram of a flexible electronic device of a fifth embodiment of the disclosure. FIG. 5B shows the stress test result when the flexible electronic device of FIG. 5A is bent. Referring to FIG. 5A and FIG. 3A at the same time, the flexible electronic device 10d of this embodiment is similar to the flexible electronic device 10b of FIG. 3A. The only difference between the two is that the flexible electronic device 10d of this embodiment also includes a third support layer 410 and a fifth adhesive layer 420.

Specifically, referring to FIG. 5A, the third support layer 410 is disposed under the first support layer 130 so that the first support layer 130 is located between the first flexible substrate 110 and the third support layer 410. The third support layer 410 has a thickness T11, and the thickness T11 may be the thickness of the third support layer 410 measured along the direction Z. In this embodiment, the thickness T11 of the third support layer 410 may be, for example, 25 microns to 500 microns, or 50 microns to 400 microns, but not limited thereto. In this embodiment, the Young's modulus of the third support layer 410 may be, for example, 0.1 GPa to 99 GPa, or 1 GPa to 10 GPa, but not limited thereto.

The fifth adhesive layer 420 is disposed between the first support layer 130 and the third support layer 410. The fifth adhesive layer 420 may be configured to bond the first support layer 130 and the third support layer 410. The fifth adhesive layer 420 has a thickness T12, and the thickness T12 may be the thickness of the fifth adhesive layer 420 measured along the direction Z. In this embodiment, the thickness T12 of the fifth adhesive layer 420 may be, for example, 10 microns to 300 microns, or 20 microns to 250 microns, but not limited thereto. In this embodiment, the Young's modulus of the fifth adhesive layer 420 may be, for example, 0.1 KPa to 10 GPa, or 100 KPa to 5 GPa, but not limited thereto. In this embodiment, the material of the fifth adhesive layer 420 may include thermosetting glue, UV glue, or a combination of the foregoing. For example, the material of the fifth adhesive layer 420 may include optically clear adhesive (OCA), optically clear resin (OCR), pressure sensitive adhesives (PSA), other suitable adhesive materials, or a combination thereof, but not limited thereto.

Referring to FIG. 5B, in the stress test result when the flexible electronic device 10d of this embodiment is bent, the stress of the electronic component 122 is reduced to approximately −2.89×10⁻⁸ MPa, and the stress of the first flexible substrate 110 is reduced to approximately 4.53×10₋₉ MPa.

Therefore, in this embodiment, by adding the third support layer 410 and the fifth adhesive layer 420, the stress of the circuit layer 120 and the first flexible substrate 110 may be further reduced or brought closer to zero. This design may enhance the bend strength of the flexible electronic device 10d or improve the repeated bending capability (number of times) of the flexible electronic device 10d, thereby reducing damage to the circuit layer 120 (e.g., circuit breakage or component damage) causing the flexible electronic device 10d to fail to operate normally (e.g., light up).

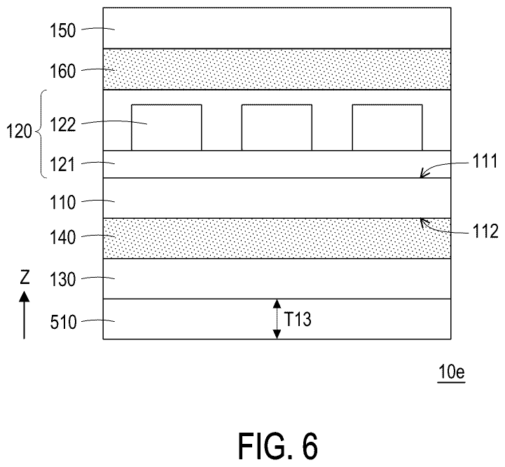

FIG. 6 is a cross-sectional schematic diagram of a flexible electronic device of a sixth embodiment of the disclosure. Referring to FIG. 6 and FIG. 1A at the same time, the flexible electronic device 10e of this embodiment is similar to the flexible electronic device 10 of FIG. 1A. The only difference between the two is that the flexible electronic device 10e of this embodiment also includes a metal layer 510.

Specifically, referring to FIG. 6, the metal layer 510 is disposed under the first support layer 130 so that the first support layer 130 is located between the first flexible substrate 110 and the metal layer 510. The metal layer 510 has a thickness T13, and the thickness T13 may be the thickness of the metal layer 510 measured along the direction Z. In this embodiment, the thickness T13 of the metal layer 510 may be, for example, 0.01 micron to 100 micron, but not limited thereto. In this embodiment, the material of the metal layer 510 may include gold, silver, copper, aluminum, platinum, other suitable metal materials, or a combination of the foregoing, but not limited thereto.

In some not-shown embodiments, the metal layer may also be embedded in the first support layer 130.

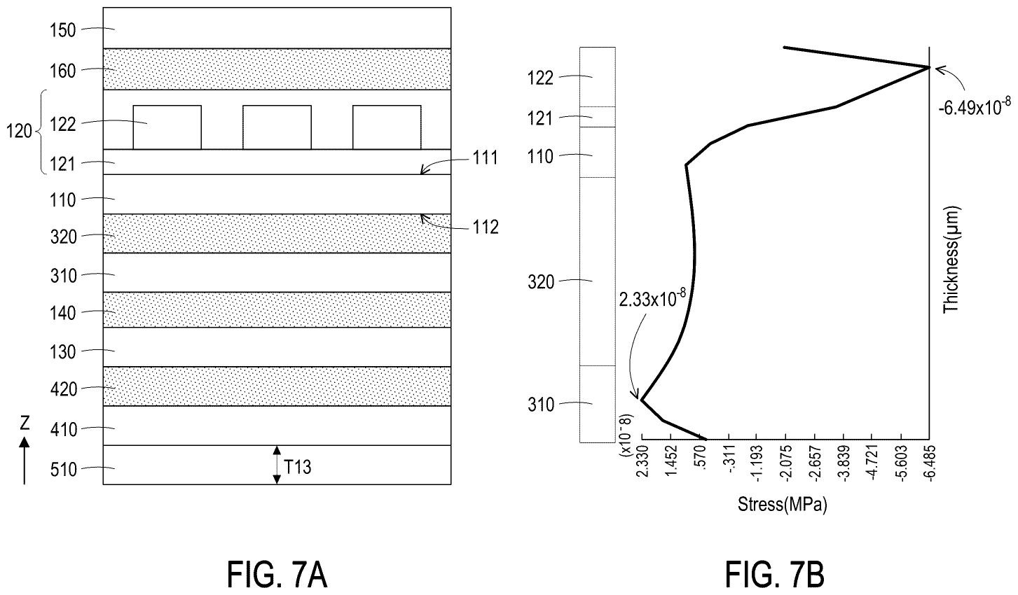

FIG. 7A is a cross-sectional schematic diagram of a flexible electronic device of a seventh embodiment of the disclosure. FIG. 7B shows the stress test result when the flexible electronic device of FIG. 7A is bent. Referring to FIG. 7A and FIG. 5A at the same time, the flexible electronic device 10f of this embodiment is similar to the flexible electronic device 10d of FIG. 5A. The only difference between the two is that the flexible electronic device 10f of this embodiment also includes a metal layer 510.

Specifically, referring to FIG. 7A, the metal layer 510 is disposed under the third support layer 410 so that the third support layer 410 is located between the first support layer 130 and the metal layer 510. The metal layer 510 has a thickness T13, and the thickness T13 may be the thickness of the metal layer 510 measured along the direction Z. In this embodiment, the thickness T13 of the metal layer 510 may be, for example, 0.01 micron to 100 micron, but not limited thereto. In this embodiment, the material of the metal layer 510 may include gold, silver, copper, aluminum, platinum, other suitable metal materials, or a combination of the foregoing, but not limited thereto.

Referring to FIG. 7B, in the stress test result when the flexible electronic device 10f of this embodiment is bent, the stress of the electronic component 122 is reduced to approximately −6.49×10⁻⁸ MPa, and the stress of the second flexible substrate 310 is reduced to approximately 2.33×10⁻⁸ MPa.

Therefore, in this embodiment, by adding the metal layer 510, the stress of the circuit layer 120 and the second flexible substrate 310 may be further reduced or brought closer to zero. This design may enhance the bend strength of the flexible electronic device 10f or improve the repeated bending capability (number of times) of the flexible electronic device 10f, thereby reducing damage to the circuit layer 120 (e.g., circuit breakage or component damage) causing the flexible electronic device 10f to fail to operate normally (e.g., light up).

In some not-shown embodiments, the metal layer may also be embedded in the first support layer 130.

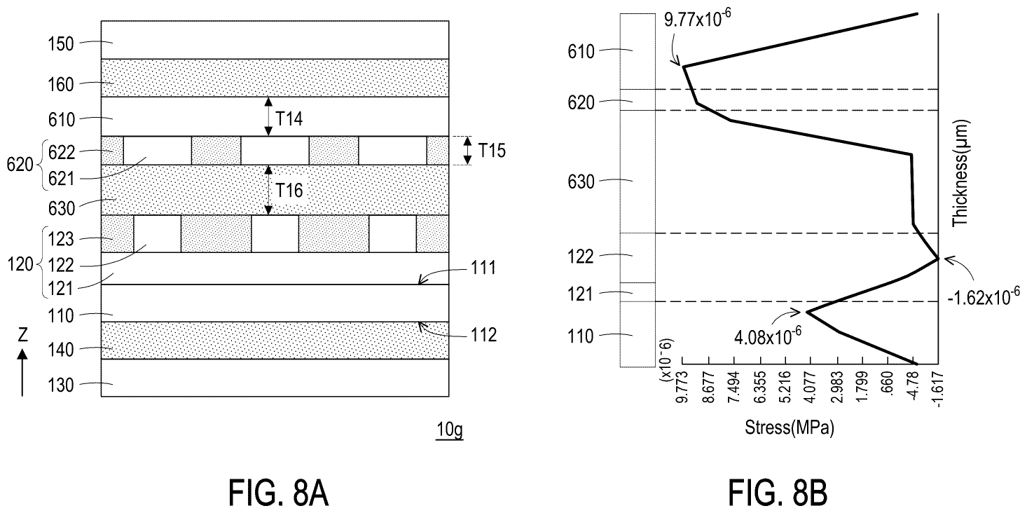

FIG. 8A is a cross-sectional schematic diagram of a flexible electronic device of an eighth embodiment of the disclosure. FIG. 8B shows the stress test result when the flexible electronic device of FIG. 8A is bent. Referring to FIG. 8A and FIG. 1A at the same time, the flexible electronic device 10g of this embodiment is similar to the flexible electronic device 10 of FIG. 1A. The only difference between the two is that the flexible electronic device 10g of this embodiment also includes a third flexible substrate 610, a filter layer 620, and a sixth adhesive layer 630.

Specifically, referring to FIG. 8A, the third flexible substrate 610 is disposed on the circuit layer 120, and the third flexible substrate 610 is disposed between the second adhesive layer 160 and the circuit layer 120. The third flexible substrate 610 has a thickness T14, and the thickness T14 may be the thickness of the third flexible substrate 610 measured along the direction Z. In this embodiment, the thickness T14 of the third flexible substrate 610 may be, for example, 1 micron to 100 microns, or 10 microns to 80 microns, but not limited thereto. In this embodiment, the Young's modulus of the third flexible substrate 610 may be, for example, 0.1 GPa to 99 GPa, or 1 GPa to 10 GPa, but not limited thereto. In this embodiment, the third flexible substrate 610 may be a soft substrate. For example, the material of the third flexible substrate 610 may include polycarbonate, polyimide, polyethylene terephthalate, fiber-reinforced plastic, other suitable plastic materials, or combinations of the foregoing, but not limited thereto.

The filter layer 620 is disposed on the circuit layer 120, the filter layer 620 is disposed

between the third flexible substrate 610 and the circuit layer 120, and the filter layer 620 is disposed on a side of the third flexible substrate 610 close to the circuit layer 120. The filter layer 620 has a thickness T15, and the thickness T15 may be the thickness of the filter layer 620 measured along the direction Z. In this embodiment, the thickness T15 of the filter layer 620 may be, for example, 1 micron to 50 microns, but not limited thereto. In this embodiment, the filter layer 620 may include a color filter layer 621 (e.g., a red filter layer, a green filter layer, a blue filter layer or other suitable color filter layers, but not limited thereto) and a black matrix 622.

The sixth adhesive layer 630 is disposed between the filter layer 620 and the circuit layer 120. The sixth adhesive layer 630 has a thickness T16, and the thickness T16 may be the thickness of the sixth adhesive layer 630 measured along the direction Z. In this embodiment, the thickness T16 of the sixth adhesive layer 630 may be, for example, 10 microns to 300 microns, or 20 microns to 250 microns, but not limited thereto. In this embodiment, the Young's modulus of the sixth adhesive layer 630 may be, for example, 0.1 KPa to 10 GPa, or 100 KPa to 5 GPa, but not limited thereto. In this embodiment, the material of the sixth adhesive layer 630 may include thermosetting glue, UV glue, or a combination of the foregoing. For example, the material of the sixth adhesive layer 630 may include optically clear adhesive (OCA), optically clear resin (OCR), pressure sensitive adhesives (PSA), other suitable adhesive materials, or a combination thereof, but not limited thereto.

The circuit layer 120 also includes spacers 123. The spacer 123 is disposed between adjacent two of the electronic components 122. The spacer (pixel define layer) 123 may overlap the black matrix 622 in the direction Z. The material of the spacer 123 may include black organic material, white organic material or transparent organic material, but not limited thereto.

Referring to FIG. 8B, in the stress test result when the flexible electronic device 10g of this embodiment is bent, the stress of the electronic component 122 is approximately −1.62×10⁻⁶ MPa, the stress of the first flexible substrate 110 is approximately 4.08×10⁻⁶ MPa, and the stress of the third flexible substrate 610 is reduced to approximately 9.77×10⁻⁶ MPa.

Therefore, in this embodiment, by adding the third flexible substrate 610, the filter layer 620 and the sixth adhesive layer 630, the stress of the circuit layer 120 may be further reduced or brought closer to zero. This design may enhance the bend strength of the flexible electronic device 10g or improve the repeated bending capability (number of times) of the flexible electronic device 10g, thereby reducing damage to the circuit layer 120 (e.g., circuit breakage or component damage) causing the flexible electronic device 10g to fail to operate normally (e.g., light up).

In some embodiments not shown, if the second flexible substrate 310, the fourth adhesive layer 320, the third support layer 410 and the fifth adhesive layer 420 are added to the flexible electronic device 10g, the stress of the driving circuit 121 may be reduced to approximately 2.55×10⁻⁶ MPa, that is, the stress of the circuit layer 120 may be further reduced or brought closer to zero.

In some embodiments not shown, if the second flexible substrate 310, the fourth adhesive layer 320, the third support layer 410 and the fifth adhesive layer 420 are added to the flexible electronic device 10g, and the thickness of the first support layer 130 and the third support layer 410 are both doubled, the stress of the driving circuit 121 may be reduced to approximately 1.89×10⁻⁶ MPa, that is, the stress of the circuit layer 120 may be further reduced or brought closer to zero.

To sum up, in the flexible electronic device according to the embodiment of the disclosure, through a design such that the circuit layer is substantially located on the neutral axis when the flexible electronic device is bent, the bend strength of the flexible electronic device may be enhanced or the repeated bending capability (number of times) of the flexible electronic device may be improved, thereby reducing damage to the circuit layer (e.g., circuit breakage or component damage) causing the flexible electronic device to fail to operate normally (e.g., light up).

Finally, it should be noted that the foregoing embodiments are only used to illustrate the technical solutions of the disclosure, but not to limit the disclosure; although the disclosure has been described in detail with reference to the foregoing embodiments, persons of ordinary skill in the art should understand that the technical solutions described in the foregoing embodiments may still be modified, or parts or all of the technical features thereof may be equivalently replaced; however, these modifications or substitutions do not deviate the essence of the corresponding technical solutions from the scope of the technical solutions of the embodiments of the disclosure.

What is claimed is:

1. A flexible electronic device, comprising:
a first flexible substrate;
a circuit layer; disposed on the first flexible substrate and comprising a driving circuit and electronic components electrically connected to the driving circuit;
a first support layer, disposed under the first flexible substrate;
a first adhesive layer, disposed between the first flexible substrate and the first support layer;
a second support layer, disposed on the circuit layer; and
a second adhesive layer, disposed between the second support layer and the circuit layer,
wherein a Young's modulus of the first support layer is greater than a Young's modulus of the first adhesive layer, and a Young's modulus of the second support layer is greater than a Young's modulus of the second adhesive layer,
wherein a thickness of the first support layer is less than a thickness of the first adhesive layer, and a thickness of the second support layer is less than a thickness of the second support layer.

2. The flexible electronic device according to claim 1, further comprising:
an anti-scattering film, disposed on the second support layer; and
a third adhesive layer, disposed between the anti-scattering film and the second support layer.

3. The flexible electronic device according to claim 2, wherein a Young's modulus of the anti-scattering film is greater than a Young's modulus of the third adhesive layer, and a thickness of the anti-scattering film is greater than a thickness of the third adhesive layer.

4. The flexible electronic device according to claim 2, wherein the second support layer is located between the anti-scattering film and the circuit layer.

5. The flexible electronic device according to claim 1, further comprising:
a second flexible substrate, disposed between the first flexible substrate and the first adhesive layer; and
a fourth adhesive layer, disposed between the first flexible substrate and the second flexible substrate.

6. The flexible electronic device according to claim 5, further comprising:
a third support layer, disposed under the first support layer; and
a fifth adhesive layer, disposed between the first support layer and the third support layer.

7. The flexible electronic device according to claim 6, wherein the first support layer is located between the first flexible substrate and the third support layer.

8. The flexible electronic device according to claim 6, further comprising:
a metal layer, disposed under the first support layer.

9. The flexible electronic device according to claim 1, further comprising:
a third support layer, disposed under the first support layer; and
a fifth adhesive layer, disposed between the first support layer and the third support layer.

10. The flexible electronic device according to claim 9, wherein the first support layer is located between the first flexible substrate and the third support layer.

11. The flexible electronic device according to claim 1, further comprising:
a metal layer, disposed under the first support layer.

12. The flexible electronic device according to claim 11, wherein the first support layer is located between the first flexible substrate and the metal layer.

13. The flexible electronic device according to claim 1, further comprising:
a metal layer, embedded in the first support layer.

14. The flexible electronic device according to claim 1, further comprising:
a third flexible substrate, disposed between the second adhesive layer and the circuit layer;
a filter layer, disposed on a side of the third flexible substrate close to the circuit layer; and
a sixth adhesive layer, disposed between the filter layer and the circuit layer.

15. The flexible electronic device according to claim 14, further comprising:
a spacer, disposed between adjacent two of the electronic components.

16. The flexible electronic device according to claim 15, wherein the filter layer comprises a color filter layer and a black matrix, and the spacer overlaps the black matrix.

17. The flexible electronic device according to claim 1, wherein the second support layer is a polarizer.

18. The flexible electronic device according to claim 1, wherein a ratio of the thickness of the first support layer to the thickness of the first adhesive layer is greater than 1/24 and less than 1.

19. The flexible electronic device according to claim 1, wherein a ratio of the thickness of the second support layer to the thickness of the second adhesive layer is greater than 1/30 and less than 1.

20. The flexible electronic device according to claim 1, wherein the circuit layer is substantially located on a neutral axis when the flexible electronic device is bent.
